(19) United States
(12) Patent Application Publication
(10) Pub. No.: US 2014/0252575 A1
(43) Pub. Date: Sep. 11, 2014

(54) LEAD FRAME FOR SEMICONDUCTOR PACKAGE

(71) Applicants: Mun Leck Shim, Mahkota Cheras (MY); Voon Kwai Leong, Sri Petaling (MY); Jhen Wei Seah, Rawang (MY)

(72) Inventors: Mun Leck Shim, Mahkota Cheras (MY); Voon Kwai Leong, Sri Petaling (MY); Jhen Wei Seah, Rawang (MY)

(21) Appl. No.: 13/789,660

(22) Filed: Mar. 7, 2013

(51) Int. Cl. H01L 23/495; H01L 21/56

(52) U.S. Cl. CPC H01L 23/495; H01L 21/56
USPC 257/667; 438/123

(57) ABSTRACT

A lead frame having a die support area for supporting a semiconductor die, a plurality of leads surrounding the die support area, and a dam bar connecting adjacent leads. The dam bar has a dummy tab between adjacent ones of the leads that transversely extends towards the die support area. The presence of the dummy tab reduces the volume of mold compound between the lead frame leads and thus, when the lead frame is cut via punching, only the lead frame is cut and not the molding material. This reduces mechanical stress during singulation significantly and as a result, the occurrence of package cracking is reduced. In addition, less mold compound at the dam bar inter-lead reduces debris during cutting, which in turn reduces debris from contaminating the package.

### BACKGROUND OF THE INVENTION

The present invention relates to integrated circuit (IC) packaging, and more particularly, to lead frames for semiconductor packages.

Many current semiconductor assembly processes include a molding operation to encapsulate a die attached to a die attach area of a lead frame, followed by a singulation process in which adjacent devices are separated. During the singulation process, a dam bar of the lead frame also is cut off and adjacent leads are separated.

FIG. 1A shows a conventional lead frame 100 having a die support area 102 for supporting a semiconductor die (not shown), a plurality of leads 104 surrounding the die support area 102, a dam bar 106 connecting adjacent leads 104, and a dam bar inter-lead area 108 between adjacent leads 104 inside the dam bar 106. FIG. 1B shows a partially assembled semiconductor device 110 including the conventional lead frame 100 after a molding operation. Molding material 112 flows to the dam bar inter-lead area 108 during the molding operation. FIG. 1C illustrates a dam bar cutting process in which the dam bar 106 is separated from the lead frame 100 with a punch 114. During this cutting process, the molding material 112 can cause mechanical stress, which can increase the occurrence of package cracking. In addition, the molding material 112 is composed mainly of silica, which is an abrasive element that tends to accelerate singulation tool wear rate. Therefore, it would be advantageous to be able to reduce the volume of molding material in the dam bar inter-lead area 108 during the molding operation.

### BRIEF DESCRIPTION OF THE DRAWINGS

The invention, together with objects and advantages thereof, may best be understood by reference to the following description of preferred embodiments together with the accompanying drawings in which:

FIG. 1A is a schematic top plan view of a conventional lead frame;

FIG. 1B is a schematic top plan view of a partially assembled semiconductor device having a conventional lead frame after a molding operation;

FIG. 1C is a sectional view of the lead frame from the line 1-1 of FIG. 1B illustrating a during dam bar cutting process;

FIG. 2A is a schematic top plan view of a lead frame in accordance with an embodiment of the present invention;

FIG. 2B is a schematic top plan view of a partially assembled semiconductor device having a lead frame in accordance with an embodiment of the present invention after a molding operation;

FIG. 2C is a sectional view of the lead frame from the line 2-2 of FIG. 2B illustrating a dam bar cutting process;

FIG. 3 is a schematic top plan view of a lead frame in accordance with another embodiment of the present invention; and

FIG. 4 is a flow chart illustrating a method of assembling a semiconductor device in accordance with an embodiment of the present invention.

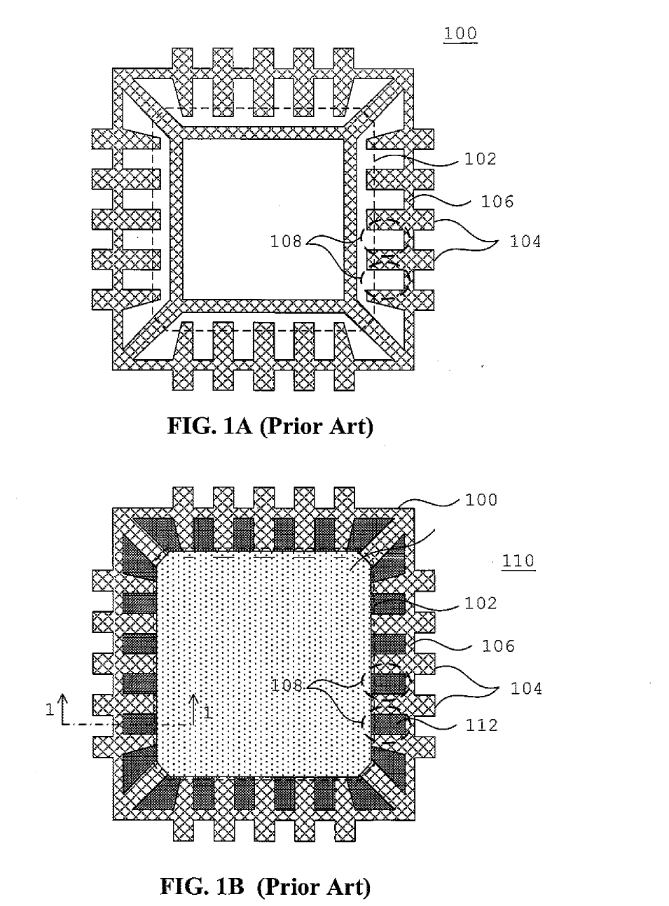

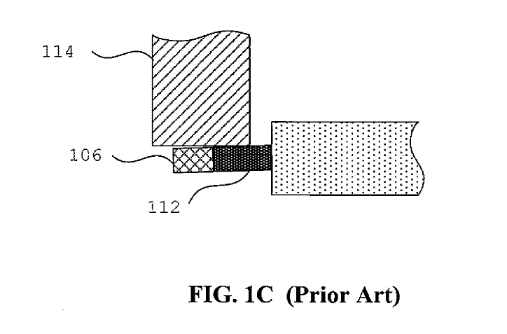

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a lead frame including a die support area for supporting a semiconductor die, a plurality of leads surrounding the die support area, and a dam bar connecting adjacent leads. The dam bar has a dummy tab located between the adjacent leads and transversely extending towards the die support area. The dummy tab reduces a volume of molding material in a dam bar inter-lead area during a molding operation.

In another embodiment, the present invention provides a method of assembling a semiconductor device including the step of providing a lead frame with a dam bar having a dummy tab between adjacent leads that transversely extends towards a die support area of the lead frame. The dummy tab reduces a volume of molding material in the dam bar inter-lead area during a molding operation.

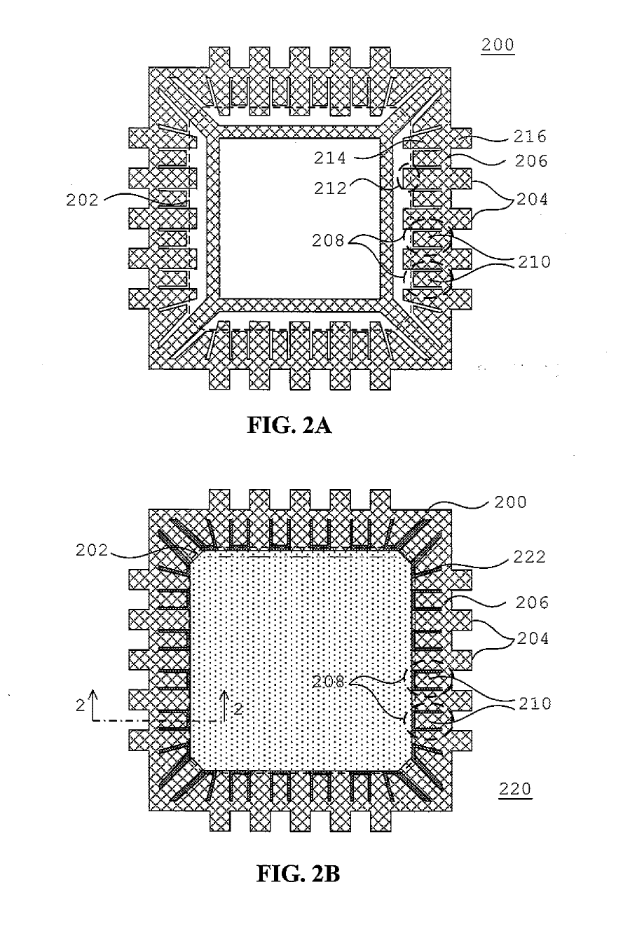

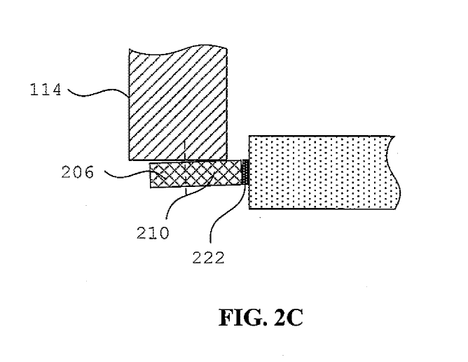

Referring now to FIG. 2A, a lead frame 200 of the present invention is shown. The lead frame 200 includes a die support area 202 (indicated in dashed lines), sometimes called a die pad or flag, for supporting a semiconductor die, a plurality of leads 204 surrounding the die support area 202, and a dam bar 206 that surrounds and is spaced from the die support area 202. Although the die support area 202 part of the lead frame 200 is shown as square or rectangular, the die support area 202 could be otherwise formed, such as with a solid or single piece of metal that supports all or nearly all of a bottom surface of a semiconductor die, or the die support area 202 could be X-shaped. Thus, the present invention is not to be limited by the construction of the die support area 202. The leads 204 are integral with and extend generally orthogonally from the dam bar 206, as is known in the art. There is a dam bar inter-lead area 208 between adjacent leads 204 inside the dam bar 206. The dam bar 206 also has dummy tabs 210 located between adjacent ones of the leads 204 and in the inter-lead areas 208. The dummy tabs 210 extend transversely towards the die support area 202.

The lead frame 200 is preferably formed from a conductive metal such as Copper, as is known in the art. The lead frame may be plated such as with Tin or other metals, also as is known in the art.

Each lead 204 has a die connect area 212. In a preferred embodiment of the invention, each lead 204 has an inner lead portion 214 and an outer lead portion 216, and the dam bar 206 connects the adjacent leads 204 at a location between the inner lead portion 214 and the outer lead portion 216. In a preferred embodiment, there is a gap between the dummy tab 210 and the adjacent leads 204. In another preferred embodiment, a length of the dummy tab 210 is less than a length of the adjacent leads 204.

Referring to FIG. 2B, a partially assembled semiconductor device 220 having a lead frame 200 in accordance with an embodiment of the present invention after a molding operation that encapsulates the semiconductor die and portions of the lead frame 200 with a molding material 222 is shown. The dam bar 206 has the dummy tabs 210 between adjacent leads 204 that extend transversely towards the die support area 202. During the molding operation, the dummy tab 210 reduces the volume of the molding material 222 in the dam bar inter-lead area 208.

FIG. 2C is a sectional view of the lead frame 200 from the line 2-2 of FIG. 2B illustrating a dam bar cutting process. In the cutting process (singulation), a punch 114 is used to cut the dam bar 206 and the dummy tab 210. Since the volume of the molding material 222 in the dam bar inter-lead area 208 has been reduced, the molding material 222 is spaced from the cutting area. As a result, the occurrence of package cracking is reduced. In addition, since the cutting tool or punch 114 does not contact with the abrasive mold material 222, the wear on the cutting tool is reduced.

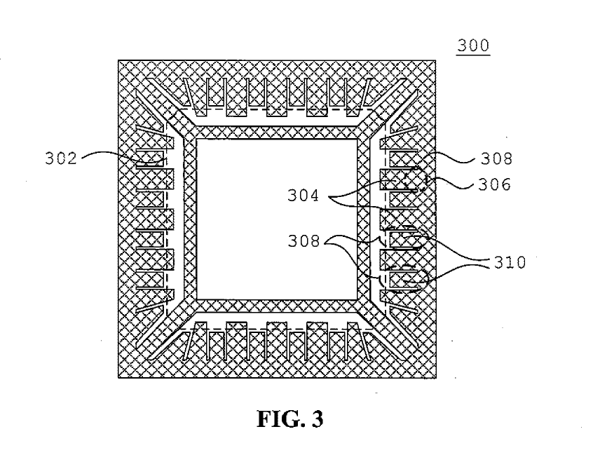

Referring to FIG. 3, a lead frame 300 according to another preferred embodiment of the present invention is shown. The lead frame 300 includes a die support area 302 for supporting a semiconductor die (not shown), a plurality of leads 304 surrounding the die support area 302, each lead 304 has an outer end 306, and a dam bar 308 connecting adjacent leads 304 at the outer ends 306. The dam bar 308 has a dummy tab 310 between the adjacent leads 304 transversely extending towards the die support area 302. In a preferred embodiment, there is a gap between the dummy tab 310 and the adjacent leads 304. In another preferred embodiment, a length of the dummy tab 310 is less than a length of the adjacent leads 304.

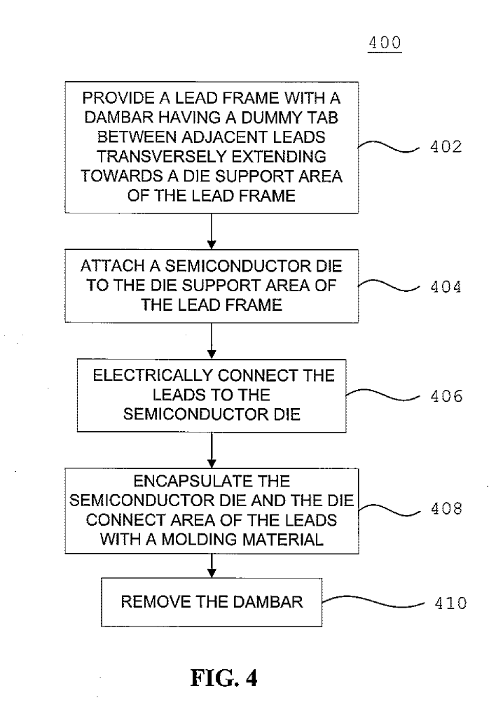

FIG. 4 is a flow chart showing the steps of a method 400 of assembling a semiconductor device with the lead frame as described above with reference to FIGS. 2A-2B and 4. The method comprises providing the lead frame 200 with the dam bar 206 having the dummy tabs 210 between adjacent leads 204 and extending transversely towards the die support area 202 of the lead frame 200. The dummy tab 210 reduces the volume of mold material proximate to the semiconductor die during a molding operation.

In more detail, the method 400 starts at 402 by providing a lead frame 200 comprising a die support area 202 for supporting a semiconductor die (not shown), a plurality of leads 204 surrounding the die support area 202, wherein each lead 204 has a die connect area 212, and a dam bar 206 connecting adjacent leads 204, wherein the dam bar 206 has a dummy tab 210 between the adjacent leads 204 transversely extending towards the die support area 202. In a preferred embodiment, the dam bar 206 connects the adjacent leads 204 at a location between the inner lead portion 214 and the outer lead portion 216. In a preferred embodiment, there is a gap between the dummy tab 210 and the adjacent leads 204. In another preferred embodiment, a length of the dummy tab 210 is less than a length of the adjacent leads 204.

In another preferred embodiment as the lead frame 300, the dam bar 308 connecting adjacent leads 304 at the outer ends 306 of the leads 304. In a preferred embodiment, there is a gap between the dummy tab 310 and the adjacent leads 304. In another preferred embodiment, a length of the dummy tab 310 is less than a length of the adjacent leads 304.

At 404, a semiconductor die (not shown) is attached to the die support area 202 of the lead frame 200, and is electrically connected to the die connect area 212 of the leads 204 at 406. The connection can be made with bond wires or solder bumps. At 408, the semiconductor die (not shown) and the die connect area 212 of the leads 204 are encapsulated with a molding material. During the molding operation, the dummy tab 210 inhibits molding material flow, therefore reduces the volume of molding material 222 in dam bar inter-lead area 208.

At 410, the dam bar 206 is removed together with the dummy tab 210. In a preferred embodiment, the removing step comprises cutting the dam bar 206 and dummy tab 210 with a punch. In another preferred embodiment, the removing step comprises removing the dam bar 206 and the dummy tab 210 with a saw. In a third preferred embodiment, the removing step comprises removing the dam bar 206 and the dummy tab 210 by laser cutting. In a fourth preferred embodiment, the removing step comprises etching the dam bar 206 and the dummy tab 210.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A lead frame, comprising:
a die support area for supporting a semiconductor die;
a plurality of leads surrounding the die support area;
a dam bar connecting adjacent leads, wherein dam bar inter-lead areas are formed between adjacent ones of the leads; and
a plurality of dummy tabs located between adjacent leads and extending transversely towards the die support area, wherein during a molding operation, the dummy tab reduces a volume of molding material in the dam bar inter-lead area.

2. The lead frame of claim 1, wherein each lead has an inner lead portion and an outer lead portion, and the dam bar connects the adjacent leads at a location between the inner lead portion and the outer lead portion.

3. The lead frame of claim 1, wherein each lead has an outer end, and the dam bar connects the adjacent leads at the outer ends.

4. The lead frame of claim 1, wherein there is a gap between the dummy tab and the adjacent leads.

5. The lead frame of claim 1, wherein a length of the dummy tab is less than a length of the adjacent leads.

6. A method of assembling a semiconductor device, comprising:
providing a lead frame comprising:
a die support area for supporting a semiconductor die,
a plurality of leads surrounding the die support area, wherein each lead has a die connect area,
a dam bar connecting adjacent ones of the leads, wherein , and
a plurality of dummy tabs located between adjacent leads and extending transversely from the dam bar towards the die support area;
attaching a semiconductor die to the die support area of the lead frame;
electrically connecting the die connect area of the leads to the semiconductor die;
encapsulating the semiconductor die and the die connect area of the leads with a molding material, wherein the dummy tab reduces a volume of molding material in the dam bar inter-lead areas; and
removing the dam bar and the dummy tab.

7. The method of assembling a semiconductor device of claim 6, wherein each lead of the lead frame has an inner lead portion and an outer lead portion, and the dam bar connects the adjacent leads at a location between the inner lead portion and the outer lead portion.

8. The method of assembling a semiconductor device of claim 6, wherein each lead of the lead frame has an outer end, and the dam bar connects the adjacent leads at the outer ends.

9. The method of assembling a semiconductor device of claim 6, wherein there is a gap between the dummy tab and the adjacent leads.

10. The method of assembling a semiconductor device of claim 6, wherein the electrically connecting step comprises electrically connecting the leads with the semiconductor die with bond wires.

11. The method of assembling a semiconductor device of claim 6, wherein the electrically connecting step comprises electrically connecting the leads with the semiconductor die with solder bumps.

12. The method of assembling a semiconductor device of claim 6, wherein the removing step comprises cutting the dam bar and the dummy tab with a punch.

13. The method of assembling a semiconductor device of claim 6, wherein the removing step comprises removing the dam bar and the dummy tab with a saw.

14. The method of assembling a semiconductor device of claim 6, wherein the removing step comprises removing the dam bar and the dummy tab by laser cutting.

15. The method of assembling a semiconductor device of claim 6, wherein the removing step comprises etching the dam bar and the dummy tab.
